(19) United States
(12) Patent Application Publication
(10) Pub. No.: US 2023/0241728 A1
(43) Pub. Date: Aug. 3, 2023

(54) MANUFACTURING METHOD OF THERMAL MODULE

(71) Applicant: ASIA VITAL COMPONENTS CO., LTD., New Taipei City (TW)

(72) Inventors: Sheng-Huang Lin, New Taipei City (TW); Yuan-Yi Lin, New Taipei City (TW)

(21) Appl. No.: 18/064,288

(22) Filed: Dec. 12, 2022

(30) Foreign Application Priority Data
Jan. 28, 2022 (TW) 111103923

(51) Int. Cl. B23P 15/26

(52) U.S. Cl. CPC B23P 15/26

(57) ABSTRACT

A manufacturing method of thermal module includes steps of: providing at least one aluminum heat conduction component and at least one copper heat conduction component; disposing a copper embedding layer, by means of physical or chemical processing, a copper embedding layer being disposed on a processed section or processed face of the aluminum heat conduction component, which processed section or processed face is correspondingly assembled with the copper heat conduction component; and welding and connecting, the surface of the aluminum heat conduction component, on which the copper embedding layer is disposed, being securely welded and connected with the copper heat conduction component so as to securely connect the aluminum heat conduction component with the copper heat conduction component. By means of the copper embedding layer, the aluminum heat conduction component can be welded and connected with other heat conduction components made of heterogeneous materials and the same material.

This application claims the priority benefit of Taiwan patent application number 111103923 filed on Jan. 28, 2022.

### BACKGROUND OF THE INVENTION

### 1. Field of the Invention

The present invention relates generally to a manufacturing method of thermal module, and more particularly to a manufacturing method of thermal module, which can improve the problem of the conventional manufacturing method of thermal module that the respective heat dissipation components made of heterogeneous materials or the same material can be hardly welded and connected with each other.

### 2. Description of the Related Art

Copper has the property of high heat conductivity. Therefore, the conventional thermal module often employs copper base seat for directly contacting a heat source to absorb the heat generated by the heat source. The copper base seat then transfers the absorbed heat to the heat pipe for speeding heat conduction and radiating fins for increasing heat dissipation area and enhancing heat dissipation efficiency. However, the thermal module employing the heat dissipation components such as all-copper-made base seat, vapor chamber, heat pipe or radiating fins has relatively heavy total weight. Also, the cost for the copper material is higher. Therefore, in recent years, the copper radiating fins and copper base seat have been gradually replaced with lightweight aluminum radiating fins and aluminum base seat of lower cost.

The copper material is replaced with the aluminum material to improve the problems of heavy weight and high material cost of the conventional thermal module. However, the aluminum material also has some shortcomings. For example, the surface of the aluminum is easy to oxidize to produce oxide of high melting point in the welding process. Under such circumstance, it is hard to fully fuse the metal at the welding seam. Therefore, it is difficult to weld the aluminum material.

In the case that the copper material is directly welded with the aluminum material, after welded, the directly mated sections of these two materials are apt to fissure due to fragility. In addition, when the copper material is fused and welded with the aluminum material, eutectic structures such as CuAl₂ are quite easy to form in the welding seam near the copper material side. The eutectic structures of CuAl₂, etc. are simply distributed over the grain boundaries of the material and easy to cause fatigue or fissure between the grain boundaries. Moreover, the melting point temperature and eutectic temperature of copper and aluminum are greatly different from each other. Therefore, in the welding operation, when aluminum is molten, the copper still keeps in solid state. When copper is molten, too much aluminum has been molten so that they cannot coexist in a co-fused or eutectic state. This increases difficulty in welding. Furthermore, pores are easy to produce at the welding seam. This is because the copper and aluminum both have very good heat conductivity. When welded, the metal in the molten pool will quickly crystallize. As a result, the metallurgy reaction gas at high temperature cannot escape in time so that pores are easy to produce. Accordingly, copper material and aluminum material cannot be directly welded with each other. It is necessary to first modify the surface of the aluminum material for successive welding operation with the copper material or other materials. In order to improve the above shortcoming that the copper material is placed with the aluminum material, while the aluminum material cannot be directly welded with the copper material or other heterogeneous material, those who are skilled in this field employ electroless nickel plating as a technique for modifying the surface of the aluminum material. The electroless nickel plating can be classified into three types: low phosphorus, middle phosphorus and high phosphorus. The electroless deposition is also termed “chemical deposition” or “autocatalytic plating”. The electroless nickel plating solution can be classified into the following three types: (1) activate/sensitize+acidic plating bath, pertaining to acidic plating solution with a pH value within 4-6. The property of such acidic plating solution is that the loss of composition amount due to the evaporation amount is less. The operation temperature is higher, but the plating solution is relatively safe and easy to control. The plating solution has high phosphorus content and high plating ratio and is often used in industrial field. (2) activate/sensitize+alkaline plating bath, pertaining to alkaline plating solution with a pH value within 8-10. The ammonia for adjusting pH value is easy to volatilize so that in operation, it is necessary supplement ammonia at proper time so as to keep the pH value stable. The plating solution has less phosphorus content and is relatively unstable and the operation temperature of the plating solution is lower. (3) HPM+alkaline plating bath. HPM is such that the silicon crystal is soaked in a mixture solution of DI-water:H₂O₂(aq):HCl(aq)=4:1:1. The oxidized layer formed on the surface of the silicon crystal substitutes for the activate/sensitize to form an autocatalytic surface on the surface.

It is necessary to use a great amount of chemical reaction liquid in the electroless nickel plating process. In addition, after the electroless nickel plating process, a great amount of industrial waste liquid containing heavy metal or chemical material will be produced. Such industrial waste liquid will produce a great amount of waste water containing toxic material such as yellow phosphorus. The waste water cannot be repeatedly used and must be recovered and treated through a dedicated unit. The waste water cannot be directly discharged so as to avoid environmental pollution. The yellow phosphorus waste water contains yellow phosphorus of a concentration ranging from 50 mg/L to 390 mg/L. Yellow phosphorus is a hypertoxic material and is greatly harmful to the organs of human body, such as the liver. After a long period of drinking water containing yellow phosphorus, a human will suffer from the lesions of osteoporosis, necrosis of mandibular bone, etc. Therefore, currently, all countries have started to prohibit such manufacturing process and promoted non-toxic manufacturing process so as to protect the environment.

It is therefore tried by the applicant to provide a manufacturing method of thermal module, in which the total weight is reduced and the chemical nickel plating is replaced with copper embedding layer as a surface modifying method for improving the problem of the conventional thermal module assembling structure that the aluminum material cannot be directly welded with other heterogeneous material. Also, the thermal module of the present invention can facilitate the welding operation without additionally producing any pollutant to pollute the environment.

### SUMMARY OF THE INVENTION

It is therefore a primary object of the present invention to provide a manufacturing method of thermal module, in which the chemical nickel plating is replaced with copper embedding layer to improve the problem of the conventional thermal module that the aluminum-made heat dissipation component cannot be directly welded with other heat dissipation components made of heterogeneous materials or the same material.

To achieve the above and other objects, the manufacturing method of thermal module of the present invention includes steps of: manufacturing method of thermal module includes steps of: providing at least one aluminum heat conduction component and at least one copper heat conduction component; disposing a copper embedding layer, by means of physical or chemical processing, a copper embedding layer being disposed on a processed section or processed face of the aluminum heat conduction component, which processed section or processed face is correspondingly assembled with the copper heat conduction component; and welding and connecting, the surface of the aluminum heat conduction component, on which the copper embedding layer is disposed, being securely welded and connected with the copper heat conduction component so as to securely connect the aluminum heat conduction component with the copper heat conduction component.

The present invention employs the copper embedding layer instead of the conventional chemical nickel plating. The copper embedding layer is disposed on the surface of a section of the aluminum-made heat dissipation component, which section is to be connected with the other heat dissipation components made of heterogeneous materials or the same material. When the aluminum-made heat dissipation component is desired to be welded with the other heat dissipation components made of heterogeneous materials or the same material, the copper embedding layer improves the problem that the aluminum-made heat dissipation component can be hardly welded with the other heat dissipation components made of heterogeneous materials or the same material. In the present invention, the conventional chemical nickel coating is replaced with copper embedding layer so that the problem caused by the chemical nickel plating can be solved.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a flow chart of the manufacturing method of thermal module of the present invention; and

FIG. 2 is a sectional assembled view showing the manufacturing method of thermal module of the present invention.

### DETAILED DESCRIPTION OF THE PREFERRED EMBODIMENTS

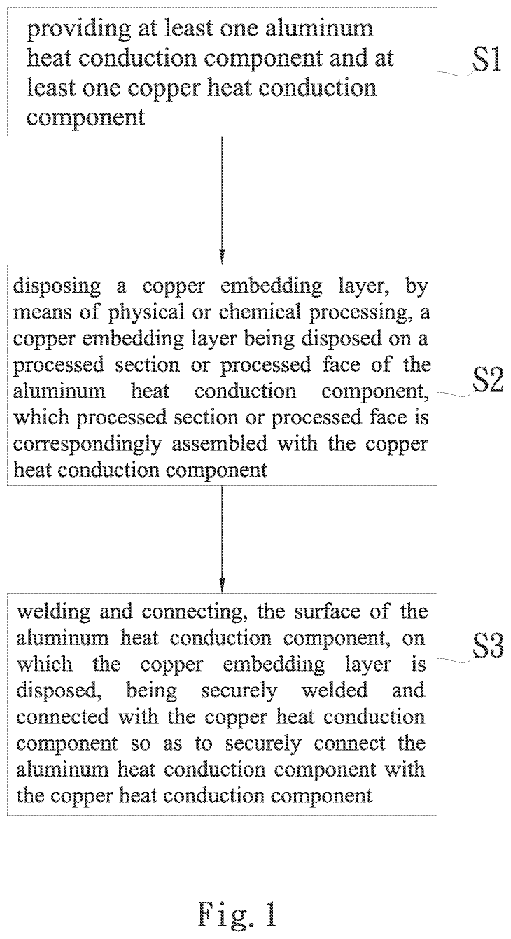

Please refer to FIG. 1, which is a flow chart of the manufacturing method of thermal module of the present invention. As shown in the drawing, the manufacturing method of thermal module of the present invention includes steps of;

S1. providing at least one aluminum heat conduction component and at least one copper heat conduction component, a copper heat conduction component or an aluminum heat conduction component being provided, the copper heat conduction component being a copper-made base seat, a copper-made substrate, a copper-made heat pipe, a copper-made vapor chamber or a copper-made water block, the aluminum heat conduction component being an aluminum-made base seat or an aluminum-made radiating fin;

S2. disposing a copper embedding layer, by means of physical or chemical processing, a copper embedding layer being disposed on a processed section or processed face of the aluminum heat conduction component, which processed section or processed face is correspondingly assembled with the copper heat conduction component, the face or the section to be processed being physically or chemically processed so as to dispose a copper embedding layer thereon, that is, by means of physical or chemical processing, the copper embedding layer being formed on a surface of the aluminum heat conduction component, which surface is to be securely assembled with the copper heat conduction component, the physical processing being a mechanical processing for deforming or cutting the surface, for example, by means of high-speed spraying, accumulating metal particles on a surface of the aluminum heat conduction component, which surface is to be securely assembled with the copper heat conduction component, to form the copper embedding layer or by means of hammering, inlaying a copper foil into a surface of the aluminum heat conduction component, which surface is to be securely assembled with the copper heat conduction component, to form the copper embedding layer, the chemical processing being selected from a group consisting of printing, electroplating, electrolysis and electroforming for disposed the copper embedding layer on the surface of the aluminum heat conduction component, by means of the copper embedding layer disposed on the surface of the aluminum heat conduction component, the shortcoming that the conventional aluminum heat conduction component can be hardly welded with the copper heat conduction component being improved; and

S3. welding and connecting, the surface of the aluminum heat conduction component, on which the copper embedding layer is disposed, being securely welded and connected with the copper heat conduction component so as to securely connect the aluminum heat conduction component with the copper heat conduction component.

In this step, the aluminum heat conduction component is connected with the copper heat conduction component by means of welding. In the welding operation, the surface of the aluminum heat conduction component, on which the copper embedding layer is disposed, is welded with the copper heat conduction component. Due to the copper embedding layer, the surface of the aluminum heat conduction component to be welded with the copper heat conduction component has the same metal element as the copper heat conduction component. Therefore, the aluminum heat conduction component can be successfully welded and connected with the copper heat conduction component.

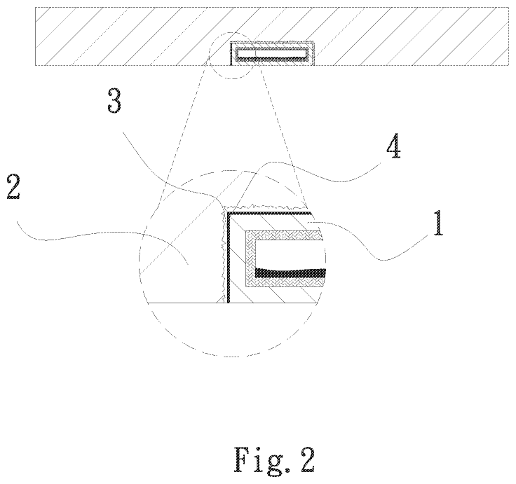

Please refer to FIG. 2, which shows that the aluminum heat conduction component 2 is correspondingly connected with the copper heat conduction component 1. The copper embedding layer 3 is disposed on a section of the aluminum heat conduction component 2, which section is in contact and connection with the copper heat conduction component 1. In addition, a welding material layer 4 is disposed between the copper embedding layer 3 and the copper heat conduction component 1, whereby the aluminum heat conduction component 2 is securely connected with the copper heat conduction component 1.

The copper heat conduction component 1 has a heat absorption section and a condensation section. The aluminum heat conduction component 2 has a connection section. The heat absorption section is correspondingly assembled with the connection section. The copper embedding layer is disposed on an outer surface of the connection section. The condensation section is correspondingly passed through multiple radiating fins made of aluminum material. By means of the copper embedding layer, the heat absorption section can be securely welded and connected with the connection section.

The copper embedding layer 3 has an embedding face and a contact face respectively positioned on two opposite faces of the copper embedding layer. The embedding face is deep engaged and inlaid in a section of the aluminum heat conduction component 2, which section is securely assembled with the copper heat conduction component 1. The contact face serves as an exposed surface of the copper embedding layer 3 and is connected with a welding material layer 4.

It can be known from the content of the specification of the present invention that after the copper embedding layer is formed on the section of the aluminum heat conduction component, which section is to be connected with the copper heat conduction component, the aluminum heat conduction component can be easily welded and connected with the copper heat conduction component by means of welding.

In the conventional manufacturing method of the thermal module, the aluminum heat conduction component (such as base seat and radiating fin assembly) must be connected with the copper heat conduction component by means of welding. However, the copper material and the aluminum material cannot be directly welded with each other. Also, the aluminum material and the aluminum material cannot be directly welded with each other. Therefore, in the conventional technique, it is necessary to first deposit a nickel coating on a section of the aluminum radiating fin, which section is connected with the aluminum base seat, or on a section of the aluminum base seat, which section is connected with the copper heat pipe by means of chemical nickel plating. In this case, the aluminum base seat, the aluminum radiating fin and the copper heat pipe can be successfully welded and connected with each other. The environmental pollution caused by the process of chemical nickel deposition has been gradually stressed and required to improve. Therefore, the present invention provides a manufacturing method of thermal module to improve the problem of environmental pollution of the conventional manufacturing method of thermal module. In the manufacturing method of thermal module of the present invention, a copper embedding layer is disposed on an outer surface of a section of the aluminum heat conduction component, which section is to be welded and connected with the copper heat conduction component. By means of the copper embedding layer, the aluminum heat conduction component and the copper heat conduction component can be successfully directly welded and connected with each other.

The present invention employs the copper embedding layer instead of the chemical electroplated nickel used in the conventional manufacturing method of thermal module so that the cost is saved and the problem of environmental pollution caused by the chemical nickel plating is improved.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A manufacturing method of thermal module, comprising steps of:
providing at least one aluminum heat conduction component and at least one copper heat conduction component;
disposing a copper embedding layer, by means of physical or chemical processing, a copper embedding layer being disposed on a processed section or processed face of the aluminum heat conduction component, which processed section or processed face is correspondingly assembled with the copper heat conduction component; and
welding and connecting, the surface of the aluminum heat conduction component, on which the copper embedding layer is disposed, being securely welded and connected with the copper heat conduction component so as to securely connect the aluminum heat conduction component with the copper heat conduction component.

2. The manufacturing method of thermal module as claimed in claim 1, wherein the copper embedding layer has an embedding face and a contact face respectively positioned on two opposite faces of the copper embedding layer, the embedding face being deep engaged and inlaid in a section of the aluminum heat conduction component, which section is securely assembled with the copper heat conduction component, the contact face serving as an exposed surface of the copper embedding layer and being connected with a welding material layer.

3. The manufacturing method of thermal module as claimed in claim 1, wherein the copper heat conduction component is a copper heat pipe, while the aluminum heat conduction component is an aluminum base seat.

4. The manufacturing method of thermal module as claimed in claim 3, wherein the copper heat conduction component has a heat absorption section and a condensation section, the aluminum heat conduction component having a connection section, the heat absorption section being correspondingly assembled with the connection section, the copper embedding layer being disposed on an outer surface of the connection section, the condensation section being correspondingly passed through multiple radiating fins made of aluminum material, whereby by means of the copper embedding layer, the heat absorption section is securely welded and connected with the connection section.
